(19) United States
(12) Patent Application Publication
(10) Pub. No.: US 2022/0359771 A1
(43) Pub. Date: Nov. 10, 2022

(54) PHOTOVOLTAIC CELL MODULE

(71) Applicant: Japan Display Inc., Tokyo (JP)

(72) Inventors: Shinichiro OKA, Tokyo (JP); Koichi IGETA, Tokyo (JP)

(73) Assignee: Japan Display Inc., Tokyo (JP)

(21) Appl. No.: 17/659,373

(22) Filed: Apr. 15, 2022

(30) Foreign Application Priority Data
May 6, 2021 (JP) 2021-078496

(51) Int. Cl. H01L 31/0232; H01L 31/054

(52) U.S. Cl. CPC H01L 31/02327; H01L 31/0543; H01L 31/0547

(57) ABSTRACT

According to one embodiment, a photovoltaic cell module includes a light guide including a first main surface, a second main surface, a first side surface, a second side surface, a third side surface and a fourth side surface, an optical element opposing the second main surface, containing a cholesteric liquid crystal forming a reflective surface inclined with respect to the second main surface, and configured to reflect at least a part of light entering from the first main surface toward the light guide, a photovoltaic cell opposing the first side surface and a reflective member opposing the second side surface, the third side surface and the fourth side surface.

### CROSS-REFERENCE TO RELATED APPLICATIONS

This application is based upon and claims the benefit of priority from Japanese Patent Application No. 2021-078496 filed May 6, 2021, the entire contents of which are incorporated herein by reference.

### FIELD

Embodiments described herein relate generally to a photovoltaic cell module.

### BACKGROUND

In recent years, various transparent photovoltaic cells have been proposed. For example, a display device with a photovoltaic cell has been proposed in which a transparent dye-sensitized photovoltaic cell is disposed on the surface of the display device.

In photovoltaic cell modules, there is a demand of improving the power generation efficiency.

### BRIEF DESCRIPTION OF THE DRAWINGS

FIG. 1 is a diagram showing an example of configuration of the appearance of a photovoltaic cell module 100.

FIG. 2 is an exploded perspective view of an example of the photovoltaic cell module 100.

FIG. 3 is a cross-sectional view showing an example of an optical element 3.

FIG. 4 is a cross-sectional view showing another example of the optical element 3.

FIG. 5 is a plan view showing an example of the photovoltaic cell module 100.

FIG. 6 is a cross-sectional view showing the example of the photovoltaic cell module 100.

FIG. 7 is a plan view showing another example of the photovoltaic cell module 100.

FIG. 8 is an exploded perspective view of another example of the photovoltaic cell module 100.

FIG. 9 is a plan view of an example of the photovoltaic cell module 100.

FIG. 10 is a plan view showing another example of the photovoltaic cell module 100.

FIG. 11 is a plan view showing another example of the photovoltaic cell module 100.

FIG. 12 is a cross-sectional view showing an example of the photovoltaic cell module 100.

### DETAILED DESCRIPTION

An object of the embodiments is to provide a photovoltaic cell module which can improve the power generation efficiency.

In general, according to one embodiment, a photovoltaic cell module comprises a light guide including a first main surface, a second main surface on an opposite side to the first main surface, a first side surface, a second side surface intersecting the first side surface, a third side surface on an opposite side to the first side surface and a fourth side surface on an opposite side to the second side, an optical element opposing the second main surface, containing a cholesteric liquid crystal forming a reflective surface inclined with respect to the second main surface, and configured to reflect at least a portion of light entering from the first main surface toward the light guide, a photovoltaic cell opposing the first side surface and a reflective member opposing the second side surface, the third side surface and the fourth side surface.

According to such configurations, it is possible to provide a photovoltaic cell module which can improve the power generation efficiency.

Embodiments will be described hereinafter with reference to the accompanying drawings. Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

Note that in order to make the descriptions easily understandable as needed, the drawings indicate an X-axis, a Y-axis and a Z-axis, which are orthogonal to each other. A direction along the X-axis is referred to as a X direction or a first direction, a direction along the Y-axis is referred to as a Y direction or a second direction, and a direction along the Z axis is referred to as a Z direction or a third direction. A plane defined by the X-axis and Y-axis is referred to as an X-Y plane. Viewing toward the X-Y plane is referred to as plan view. The first direction X and the second direction Y correspond to the directions parallel to the main surface of the substrate contained the photovoltaic cell module, and the third direction Z corresponds to the thickness direction of the photovoltaic cell module.

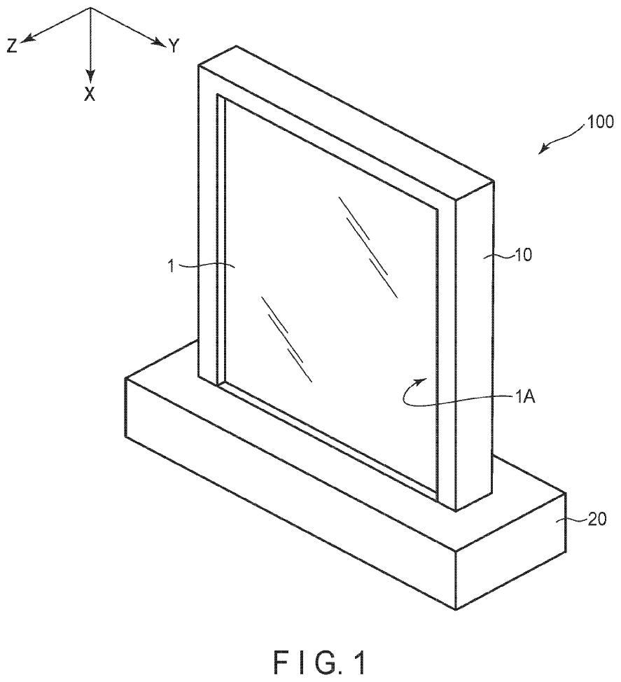

FIG. 1 is a diagram showing an example of the appearance of the photovoltaic cell module 100.

The photovoltaic cell module 100 comprises a light guide 1, a frame 10 and a power generator 20. The light guide 1 functions, for example, as a window glass. The light guide 1 is not limited to a transparent glass plate, but may be formed from a transparent synthetic resin plate. Further, the light guide 1 may be flexible. FIG. 1 shows the photovoltaic cell module 100 viewed from an outdoor side. The light guide 1 includes a first main surface 1A facing outdoors. The frame 10 surrounds three sides of the light guide 1. The power generator 20 is provided along the other one side of the light guide 1. The power generator 20 comprises a photovoltaic cell, which will be described later.

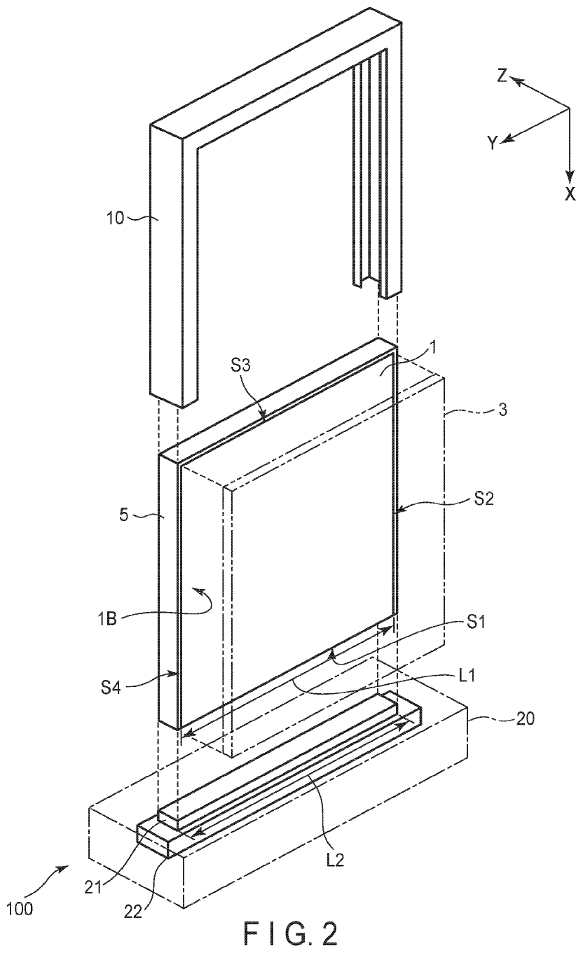

FIG. 2 is an exploded perspective view showing an example of the photovoltaic cell module 100. FIG. 2 shows the photovoltaic cell module 100 viewed from an indoor side. The photovoltaic cell module 100 further comprises an optical element 3 indicated by double-dotted lines, and a reflective member 5, in addition to the light guide 1, the frame 10 and the power generator 20 indicated by single dotted lines.

The light guide 1 further includes, in addition to the first main surface 1A, a second main surface 1B, a first side surface S1, a second side surface S2, a third side surface S3 and a fourth side surface S4. The second main surface 1B is a surface on an opposite side to the first main surface 1A shown in FIG. 1 and faces, for example, indoors. The first main surface 1A and the second main surface 1B are surfaces parallel to the X-Y plane.

The first side surface S1 and the third side surface S3 extend along the second direction Y. The second side surface S2 and the fourth side surface S4 extend along the first direction X and intersect the first side surface S1. The third side surface S3 is a surface on an opposite side to the first side surface S1. The fourth side surface S4 is a surface on an opposite side to the second side surface S2.

The optical element 3 opposes the second main surface 1B in the third direction Z. Details of the optical element 3 will be described later.

The reflective member 5 opposes the second side surface S2 and the fourth side surface S4 in the second direction Y, and opposes the third side surface S3 in the first direction X. The reflective member 5 does not oppose the first side surface S1. The reflective member 5 may contain a metal material with high reflectivity, such as silver, aluminum or the like, or it may be an interference film in which transparent films having different refractive indices are stacked on one another. The reflective member 5 having such a configuration may be a reflective layer formed directly on each side surface or a separately formed reflective film, as will be described in detail later. The reflective film is adhered to each side surface via a transparent adhesive layer.

In the example illustrated, the reflective member 5 is arranged to cover the entire area of each side surface, but the arrangement is not limited to that of this example. For example, the reflective member 5 may be arranged to cover a portion of each side surface (for example, portions of the second side surface S2 and the fourth side surface S4, which are proximate to the first side surface S1), or it may be arranged in dots (scattered islands) on each side surface.

The frame 10 is formed to enclose each of the second side surface S2, the third side surface S3, and the fourth side surface S4.

The power generator 20 comprises a photovoltaic cell 21. The photovoltaic cell 21 is placed on a substrate 22. The photovoltaic cell 21 opposes the first side surface S1 in the first direction X.

The photovoltaic cell 21 receives light and converts the energy of the received light into electric power, and is a type of photoelectric conversion element. That is, the photovoltaic cell 21 is of a type which generates electricity from the received light, but the type of the photovoltaic cell 21 is not particularly limited. For example, the photovoltaic cell 21 is a silicon photovoltaic cell, compound semiconductor photovoltaic cell, organic semiconductor photovoltaic cell, perovskite photovoltaic cell or quantum dot photovoltaic cell.

For example, the photovoltaic cell 21 is configured to receive infrared light to generate electricity.

The photovoltaic cell 21 extends along the first direction X. The photovoltaic cell 21 is disposed over a range equal to or greater than the length of the first side surface S1 along its extending direction. In other words, when the length of the first side surface S1 along the first direction X is represented by L1 and the length of the photovoltaic cell 21 along the first direction X is represented by L2, the length L2 is equal to or greater than the length L1 (L1≤L2).

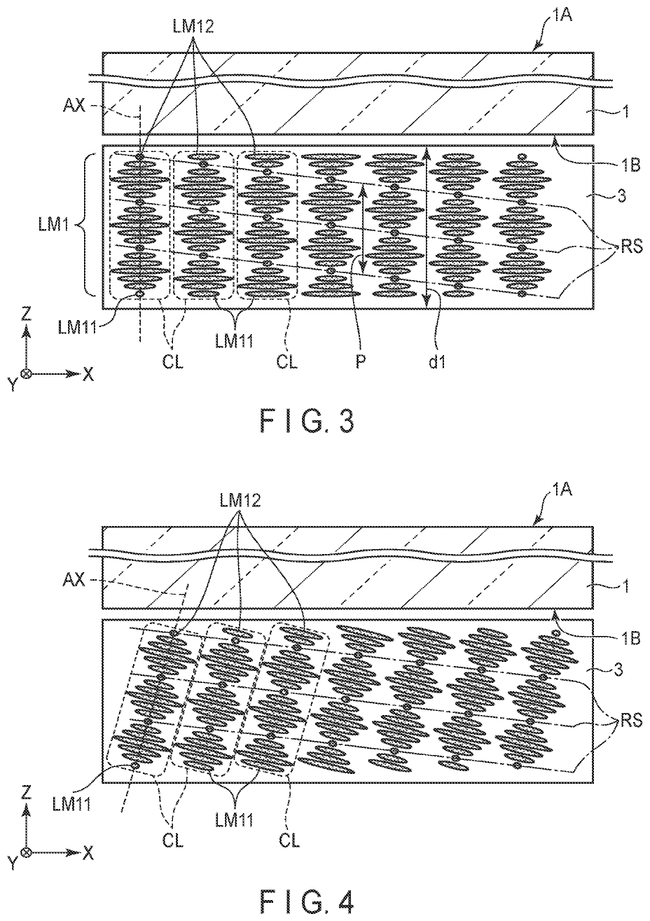

FIG. 3 is a cross-sectional view showing an example of the optical element 3. The optical element 3 functions as a reflective polarization diffraction grating.

The optical element 3 is a liquid crystal layer containing cholesteric liquid crystals CL. FIG. 3 illustrates, for the sake of simplicity, one liquid crystal molecule LM1 of liquid crystal molecules located in the same plane parallel to the X-Y plane, which constitutes the cholesteric liquid crystal CL, and the alignment direction of the liquid crystal molecule LM1 is equivalent to the average alignment direction of the longitudinal axes of the liquid crystal molecules located in the same plane. The optical element 3 has a thickness d1 along the third direction Z.

Focusing on one cholesteric liquid crystal CL, the cholesteric liquid crystal CL includes a liquid crystal molecule LM11 located at one end side and a liquid crystal molecule LM12 located at the other end side. The liquid crystal molecules LM1, which include the liquid crystal molecule LM11 and the liquid crystal molecule LM12, are accumulated in a spiral shape while rotating around a helical axis AX to form the cholesteric liquid crystal CL.

The cholesteric liquid crystal CL has a helical pitch P. The helical pitch P is one cycle of the helix (that is, the thickness along the helical axis AX, which requires for the liquid crystal molecule LM1 to rotate 360 degrees). In the example shown in FIG. 3, the helical axis AX is parallel to the third direction Z, which is the normal direction of the optical element 3.

In the optical element 3, the cholesteric liquid crystals CL are arranged along the first direction X as well as the second direction. Each adjacent pair of the cholesteric liquid crystals CL along the first direction X have alignment directions different from each other. The alignment directions of the liquid crystal molecules LM11 arranged along the first direction X vary one from another continuously. Similarly, the alignment directions of the liquid crystal molecules LM12 arranged along the first direction X vary one from another continuously.

The optical element 3 includes a plurality of reflective surfaces RS, as indicated by single-dotted lines. The reflective surfaces RS are substantially parallel to each other. The reflecting surfaces RS reflect the first circularly polarized light of a specific wavelength of the incident light and transmit the second circularly polarized light which rotates opposite to the first circularly polarized light according to Bragg's law. The reflection surfaces RS here are each equivalent to a plane where the alignment directions of the liquid crystal molecules LM1 are matched or where the spatial phases thereof are matched (an equiphase surface). In the X-Z cross section shown in FIG. 3, the reflection surfaces RS are inclined with respect to the second main surface 1B or the X-Y plane. Note that in this specification, the circularly polarized light may be strictly circularly polarized light or circularly polarized light approximating to elliptically polarized light.

The cholesteric liquid crystals CL reflect circularly polarized light of a specific wavelength λ that has the same rotational direction as that of the cholesteric liquid crystals CL. For example, when the rotational direction of the cholesteric liquid crystals CL is rightward, they reflect rightward circularly polarized light and transmit leftward circularly polarized light, of light of the specified wavelength λ. Similarly, when the rotational direction of the cholesteric liquid crystals CL is leftward, they reflect leftward circularly polarized light and transmit rightward circularly polarized light, of the light of the specified wavelength λ.

The optical element 3 with such a configuration is cured in a state that the alignment direction of the liquid crystal molecules LM1, including the liquid crystal molecule LM11 and the liquid crystal molecule LM12 is fixed. In other words, the alignment direction of the liquid crystal molecule LM1 is not controlled in response to an electric field. Therefore, the optical element 3 does not include electrodes for alignment control.

In general, the selective reflection band Δλ of the cholesteric liquid crystals CL for vertically entering light is represented by “no*P˜ne*P”, based on the helical pitch P of the cholesteric liquid crystals CL, the refractive index ne for extraordinary light and the refractive index no for ordinary light. Thus, in order to efficiently reflect circularly polarized light of a specific wavelength λ at the reflective surfaces RS, the helical pitch P, the refractive indexes ne and no are set so that the specific wavelength λ is contained in the selective reflection band Δλ.

Here, the helical pitch P of the cholesteric liquid crystals CL is adjusted so that the selected reflection band Δλ is of infrared. From the viewpoint of increasing the reflectance at the reflective surfaces RS of the optical element 3, it is preferable that the thickness d1 of the optical element 3 should be several times to about ten times the value of the helical pitch P. That is, the thickness of the optical element 3 is about 3 to 10 μm.

In the example shown in FIG. 3, the optical element 3 is separated from the light guide 1, but the configuration is not limited to that of this example. For example, if the optical element 3 is formed as a separate film, the optical element 3 is adhered to the light guide 1 via a transparent adhesive layer. Further, the optical element 3 may be formed using the light guide 1 as a base. In this case, between the light guide 1 and the optical element 3, an alignment film having a predetermined alignment pattern is interposed.

Moreover, a plurality of optical elements 3 may be stacked along the third direction Z. For example, when two optical elements 3 which has the identical helical pitch P of the cholesteric liquid crystals CL contained in each respective optical element 3 and rotation directions of the helix opposite to each other are stacked one on another, the combination can be configured to reflect not only the first circularly polarized light of a specific wavelength λ, but also the second circularly polarized light having a rotation direction opposite to that of the first circularly polarized light.

Further, by stacking a plurality of optical elements 3 having helical pitches P of the cholesteric liquid crystals CL contained in each respective optical element 3 different from each other, the selective reflection band Δλ can be broadened.

FIG. 4 is a cross-sectional view showing another example of the optical element 3.

The example shown in FIG. 4 is different from that of FIG. 3 in that the helical axis AX of the cholesteric liquid crystals CL is inclined with respect to the normal direction (third direction Z) of the optical element 3.

In the optical element 3, each adjacent pair of a plurality of cholesteric liquid crystals CL arranged along the first direction X have alignment directions different from each other. The alignment directions of the liquid crystal molecules LM11 arranged along the first direction X vary one from another continuously. Similarly, the alignment directions of the liquid crystal molecules LM12 arranged along the first direction X vary one from another continuously.

The optical element 3 includes a plurality of reflective surfaces RS, as indicated by single-dotted lines. The reflective surfaces RS are substantially parallel to each other. The reflecting surfaces RS reflect a portion of circularly polarized light of the incident light and transmit the other portion thereof according to Bragg's law. In the X-Z cross section shown in FIG. 4, the reflection surfaces RS are inclined with respect to the second main surface 1B or the X-Y plane.

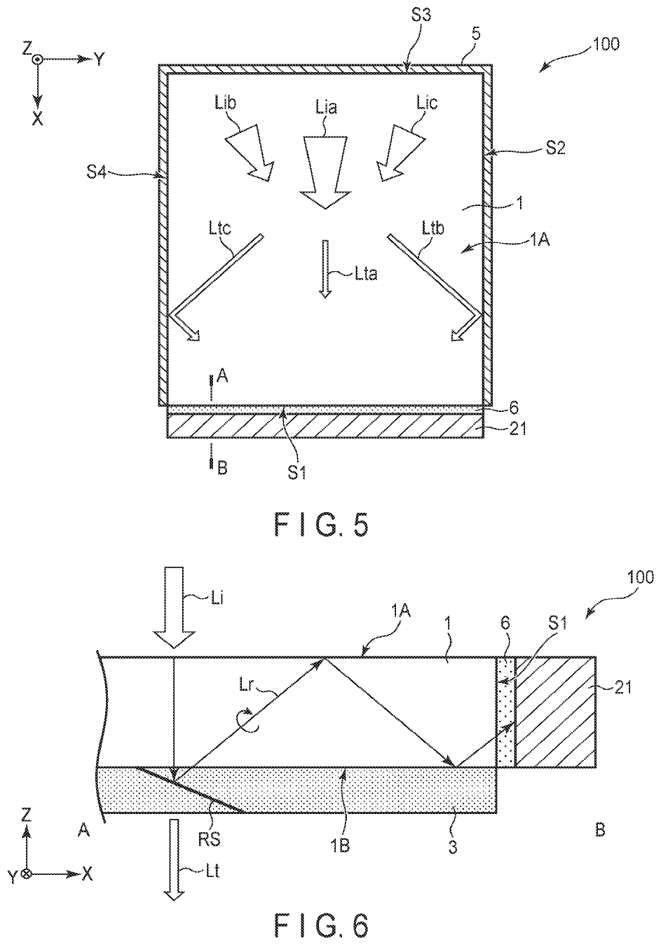

FIG. 5 is a plan view showing an example of the photovoltaic cell module 100.

In the example shown in FIG. 5, the reflective member 5 is formed directly on each of the second side surface S2, the third side surface S3 and the fourth side surface S4. The reflective member 5 with such a configuration is, for example, a reflective layer formed by applying a paste containing a metal material such as silver, followed by curing or depositing a metal material.

The photovoltaic cell 21 is adhered to the first side surface S1 via the transparent adhesive layer 6.

FIG. 6 is a cross-sectional view showing the example of the photovoltaic cell module 100. FIG. 6 is equivalent to a cross-sectional view of the photovoltaic cell module 100 taken along line A-B of FIG. 5.

The operation of the photovoltaic cell module 100 will now be described.

Light Li entering the first main surface 1A of the light guide 1 is, for example, sunlight. That is, the light Li contains infrared light in addition to visible light.

The light Li passes through the light guide 1 and enters the optical element 3. The optical element 3 reflects a part of light Lr of the light Li, toward the light guide 1 and the photovoltaic cell 21 and transmits the other part of light Lt. The light Lr reflected on the reflecting surface RS of the optical element 3 is, for example, the first circularly polarized light of infrared light. The light Lt transmitted through the optical element 3 contains the second circular polarization of infrared light and visible light.

Note here, as described above, when two optical elements 3 with the same helical pitch P and opposite helix rotation directions are stacked on one another, both the first circularly polarized light and the second circularly polarized light of the infrared light are reflected by the optical element 3.

The light Lr reflected by the optical element 3 again enters the light guide 1 and propagates inside the light guide 1 while repeating reflection in the light guide 1.

The photovoltaic cell 21 receives the light Lr emitted from the first side surface S1 and generates electricity.

Referring again to FIG. 5, light Lia traveling from the front side of the photovoltaic cell module 100 toward the first main surface 1A is reflected substantially toward the front inside the photovoltaic cell module 100, and propagates toward the photovoltaic cell 21 as light Lta. Light Lib traveling from a direction oblique with respect to the photovoltaic cell module 100 toward the first main surface 1A is reflected in a direction toward the second side surface S2 inside the photovoltaic cell module 100. The reflected light Ltb propagates toward the second side surface S2, is reflected by the reflective member 5 and then propagates toward the photovoltaic cell 21. Similarly, light Lic traveling from a direction oblique with respect to the photovoltaic cell module 100 toward the first main surface 1A is reflected in a direction toward the fourth side surface S4 inside the photovoltaic cell module 100. The reflected light Ltc propagates toward the fourth side surface S4, is reflected by the reflective member 5 and then propagates toward the photovoltaic cell 21.

Further, light that spreads and propagates within the plane of the light guide 1, such as light scattered by the light guide 1, light reflected by the reflective surfaces RS, and light refracted at the interface between the optical members, reaches the second side surface S2, the third side surface S3 and the fourth side surface S4, and then is reflected by the reflective members 5. After that, it propagates toward the photovoltaic cell 21.

That is, light leakage, which may occur at the second side surface S2, the third side surface S3 and the fourth side surface S4 is suppressed.

Further, as described with reference to FIG. 2, the photovoltaic cell 21 is disposed over a range of the length equal to or greater than the length of the first side surface S1. With this configuration, the light propagating toward the photovoltaic cells 21 can be used to generate electricity.

Thus, the power generation efficiency can be improved.

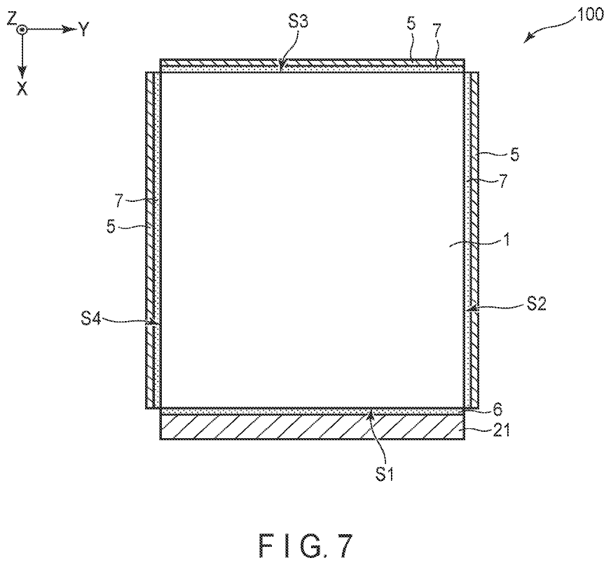

FIG. 7 is a plan view showing another example of the photovoltaic cell module 100.

In the example shown in FIG. 7, the reflective member 5 is adhered to the second side surface S2, the third side surface S3 and the fourth side surface S4 via adhesive layers 7, respectively. The reflective member 5 having such a configuration is, for example, a pre-formed reflective film. The adhesive layers 7 should preferably be formed of a material having low scattering property or a transparent material.

In the example illustrated, three reflective films, which constitute the reflective members 5, are respectively adhered to the second side surface S2, the third side surface S3 and the fourth side surface S4. Note that a series of reflective films may be adhered to the three side surfaces without interruption.

In the example with such a configuration, advantageous effects similar to those described above can be obtained. In addition, the process of adhering the reflective films as the reflective members 5 is easier than the process of applying the paste, followed by curing, or depositing a reflective material. Further, even if the light guide 1 is larger in size, the reflective member 5 can be easily formed.

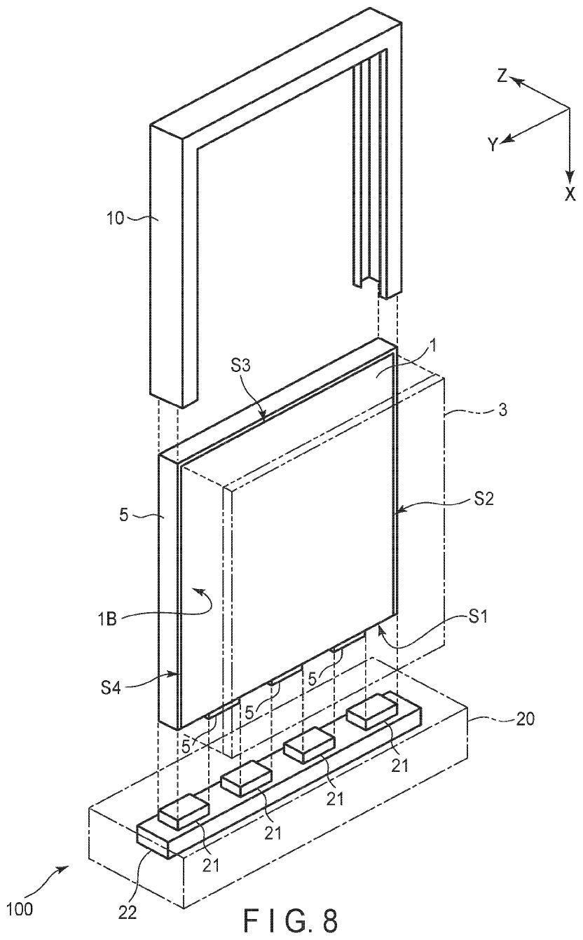

FIG. 8 is an exploded perspective view showing another example of the photovoltaic cell module 100. The example shown in FIG. 8 is different from that of FIG. 2 in that the power generator 20 comprises a plurality of photovoltaic cells 21. The photovoltaic cells 21 are arranged so as to be spaced apart from each other along the second direction Y, which is the extending direction of the first side surface S1. The photovoltaic cells 21 are placed on a common substrate 22. Each of the photovoltaic cells 21 opposes the first side surface S1 in the first direction X.

The reflective member 5 is disposed to oppose each of the second side surface S2, the third side surface S3, the fourth side surface S4 and to oppose the first side surface S1 between each pair of photovoltaic cells 21 adjacent to each other in the second direction Y.

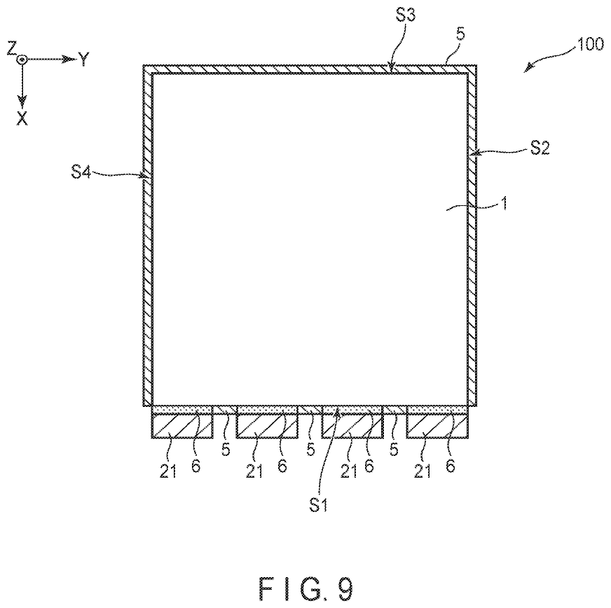

FIG. 9 is a plan view showing an example of the photovoltaic cell module 100.

In the example shown in FIG. 9, the reflective member 5 is formed directly on each of the second side surface S2, the third side surface S3, and the fourth side surface S4. Further, the reflective member 5 is formed directly on the first side surface S1 between each adjacent pair of the photovoltaic cells 21. Such reflective member 5 is, for example, a reflective layer formed by applying a paste containing a metal material such as silver, followed by curing, or vapor-depositing the metal material.

The photovoltaic cells 21 are each adhered to the first side surface S1 via a respective transparent adhesive layer 6.

According to the example with such a configuration, light leakage from between adjacent photovoltaic cells 21 on the first side surface S1 can be suppressed. Thus, advantageous effects similar to those described with reference to FIGS. 5, 6 and the like can be obtained.

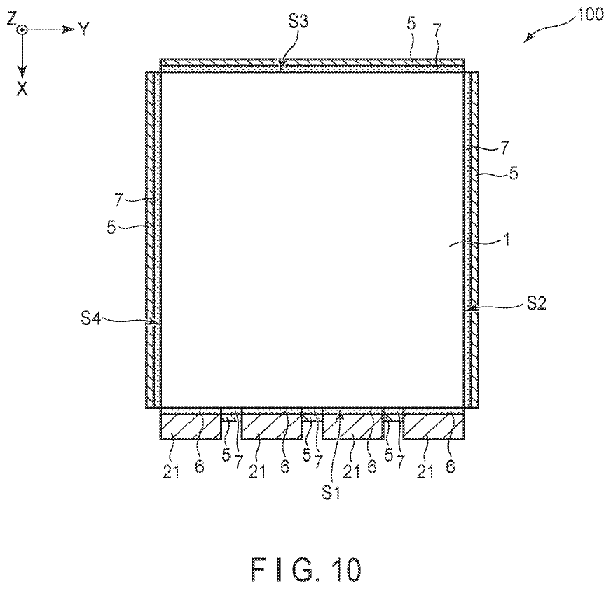

FIG. 10 is a plan view showing another example of the photovoltaic cell module 100.

In the example shown in FIG. 10, the reflective member 5 is adhered to each of the second side surface S2, the third side surface S3 and the fourth side surface S4 via respective adhesive layers 7, respectively. The reflective member 5 is also adhered to the first side surface S1 between each adjacent pair of the photovoltaic cells 21 via adhesive layers 7, respectively. The reflective member 5 is, for example, a pre-formed reflective film. The adhesive layers 7 should preferably be formed of a material with low scattering property or a transparent material.

In the example illustrated, three reflective films, which constitute the reflective members 5, are respectively adhered to the second side surface S2, the third side surface S3 and the fourth side surface S4. Note that a series of reflective films may be adhered onto the three side surfaces without interruption.

In the example with such a configuration, advantageous effects similar to those described with reference to FIG. 7 can be obtained.

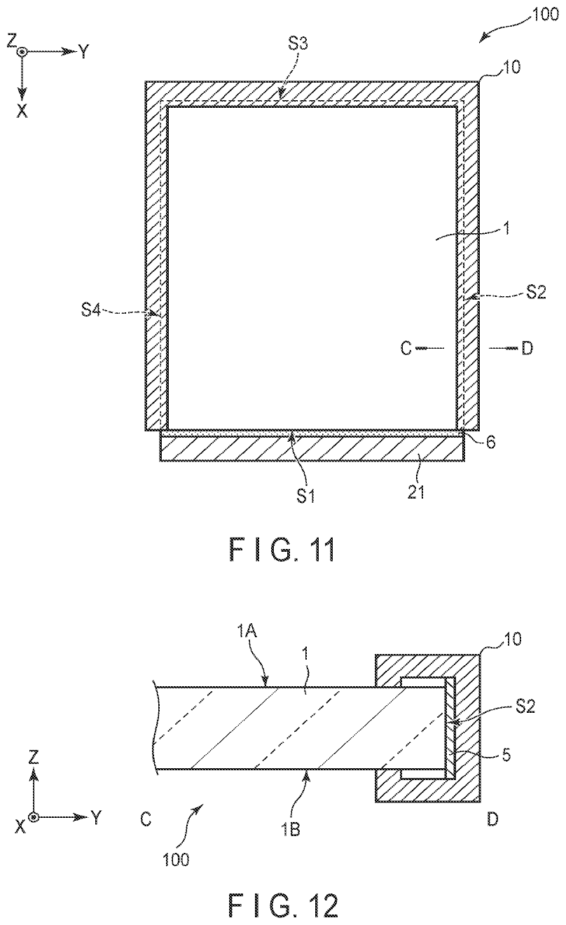

FIG. 11 is a plan view showing another example of the photovoltaic cell module 100.

In the example shown in FIG. 11, the above-described reflective layers are not formed on any of the second side surface S2, the third side surface S3 and the fourth side surface S4, or the above-described reflective films are not adhered. The second side surface S2, the third side surface S3 and the fourth side surface S4 are surrounded by the frame 10, and further, these surfaces respectively oppose reflective members formed on inner sides of the frame 10, as will be described below.

In the example illustrated, a single photovoltaic cell 21 is adhered to the first side surface S1 by the adhesive layer 6, but, as shown in FIG. 9, a plurality of photovoltaic cells 21 may be adhered to the first side surface S1, respectively, by adhesive layers 6.

FIG. 12 is a cross-sectional view showing the photovoltaic cell module 100. FIG. 12 is equivalent to the cross-sectional view showing the photovoltaic cell module 100 taken along line C-D in FIG. 11. In FIG. 12, the optical element 3 is omitted from illustration.

The reflective member 5 is a reflective surface formed on an inner side of the frame 10. The reflective surface may be a metal surface or a mirror surface. In the cross-section including the second side surface S2 shown in the figure, the reflective member 5 opposes the second side surface S2. In the example illustrated, the reflective member 5 is in contact with the second side surface S2, but may be spaced apart from the second side surface S2.

The reflective member 5 with such a configuration is formed over substantially the entire inner side of the frame 10. Therefore, in the cross-section including the third side surface S3, similarly, the reflective members 5 opposes the third side surface S3, and in the cross-section including the fourth side surface S4, similarly, the reflective member 5 opposes the fourth side surface S4.

According to the example shown in FIGS. 11 and 12, even if light propagating through the light guide 1 leaks out from the second side surface S2, the third side surface S3 and the fourth side surface S4, the leaking light is reflected by the reflective surfaces back to the light guide 1, and propagates therein to be used for power generation. Thus, the power generation efficiency can be improved as in the case of the examples described above.

As explained above, according to the embodiments, it is possible to provide a photovoltaic cell module that can improve the power generation efficiency.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A photovoltaic cell module comprising:
a light guide including a first main surface, a second main surface on an opposite side to the first main surface, a first side surface, a second side surface intersecting the first side surface, a third side surface on an opposite side to the first side surface and a fourth side surface on an opposite side to the second side;
an optical element opposing the second main surface, containing a cholesteric liquid crystal forming a reflective surface inclined with respect to the second main surface, and configured to reflect at least a part of light entering from the first main surface toward the light guide;
a photovoltaic cell opposing the first side surface; and
a reflective member opposing the second side surface, the third side surface and the fourth side surface.

2. The photovoltaic cell module of claim 1, wherein
the reflective member is a reflective layer formed directly on the second side surface, the third side surface and the fourth side surface.

3. The photovoltaic cell module of claim 1, wherein
the reflective member is a reflective film adhered to the second side surface, the third side surface and the fourth side surface via an adhesive layer.

4. The photovoltaic cell module of claim 1, further comprising:
a frame surrounding the second side surface, the third side surface and the fourth side surface,
wherein
the reflective member is a reflective surface formed on an inner side of the frame.

5. The photovoltaic cell module of claim 1, wherein
the photovoltaic cell is adhered to the first side surface via an adhesive layer.

6. The photovoltaic cell module of claim 1, wherein
the photovoltaic cell is disposed over a range equal to or greater than a length of the first side surface along an extending direction thereof.

7. The photovoltaic cell module of claim 1, further comprising a plurality of photovoltaic cells including the photovoltaic cell,
wherein
the plurality of photovoltaic cells arranged to be spaced apart from each other along an extending direction of the first side surface, and
the reflective member opposes the first side surface between the photovoltaic cells.
